(19) United States
(12) Patent Application Publication
(10) Pub. No.: US 2011/0237216 A1
(43) Pub. Date: Sep. 29, 2011

(54) BANDPASS FILTER, AND WIRELESS COMMUNICATION MODULE AND WIRELESS COMMUNICATION DEVICE USING THE BANDPASS FILTER

(76) Inventors: Hiromichi Yoshikawa, Kagoshima (JP); Masafumi Horiuchi, Kagoshima (JP)

(21) Appl. No.: 13/131,236

(22) PCT Filed: Nov. 24, 2009
(86) PCT No.: PCT/JP2009/069792

§ 371 Date: May 25, 2011

(30) Foreign Application Priority Data
Nov. 26, 2008 (JP) 2008300730
Feb. 25, 2009 (JP) 2009041983

(51) Int. Cl. H04B 1/16; H03H 7/00

(52) U.S. Cl. 455/339; 333/185

(57) ABSTRACT

[Object] An object is to provide a bandpass filter that can be used for a wide frequency band and has a large degree of freedom in designing a passband, and a wireless communication module and a wireless communication device that use the bandpass filter.

[Solution] A bandpass filter includes first to third resonance electrodes 31a, 31b, and 31c sequentially arranged side-by-side such that they are electromagnetically coupled to each other, the first to third resonance electrodes 31a, 31b, and 31c being grounded at one end and constituting first to third resonators, respectively; a first input/output coupling electrode 40a facing the first resonance electrode 31a and electromagnetically coupled thereto; a second input/output coupling electrode 40b facing the second resonance electrode 31b and electromagnetically coupled thereto; and a resonator coupling electrode 43 configured to provide electromagnetic coupling between the first resonance electrode 31a and the third resonance electrode 31c. The first and second resonators have the same resonance frequency which is different from a resonance frequency of the third resonator. The first to third resonators are used to produce a passband. The bandpass filter can be used for a wide frequency band and has a large degree of freedom in designing the passband.

### TECHNICAL FIELD

The present invention relates to a bandpass filter that can be used for a wide frequency band and has a large degree of freedom in designing a passband, and further relates to a wireless communication module and a wireless communication device that use the bandpass filter.

### BACKGROUND ART

In an electronic apparatus, such as a communication device, a bandpass filter that passes electric signals of only specific frequencies is used. In particular, a bandpass filter is widely used, which forms a passband including an even-mode resonance frequency and an odd-mode resonance frequency by using even mode resonance and odd mode resonance in a resonance system in which two resonators having the same resonance frequency are electromagnetically coupled to each other. In this bandpass filter, a difference between the even-mode resonance frequency and the odd-mode resonance frequency varies depending on the strength of electromagnetic coupling between the two resonators. The passband width of the bandpass filter is thus determined (see, e.g., Patent Literature (PTL) 1).

### Citation List

### Patent Literature

PTL 1: Japanese Unexamined Patent Application Publication No. 7-30303

### SUMMARY OF INVENTION

### Technical Problem

However, since the above-described bandpass filter of the related art forms a passband using two resonance peaks which are an even-mode resonance peak and an odd-mode resonance peak, there are limitations in using the bandpass filter for a wide frequency band. Another bandpass filter is also known, which forms a passband by using three resonance peaks of three resonance modes in a resonance system in which three resonators having the same resonance frequency are electromagnetically coupled to each other. This bandpass filter can be used for a wider frequency band. However, since it is difficult to individually set the frequencies of three resonance peaks to any values, the degree of freedom in designing the passband is small.

The present invention has been devised in view of the problems with the related art described above. An object of the present invention is to provide a bandpass filter that can be used for a wide frequency band and has a large degree of freedom in designing a passband, and also to provide a wireless communication module and a wireless communication device that use the bandpass filter.

### Solution to Problem

A bandpass filter according to the present invention includes a laminated body formed by stacking a plurality of dielectric layers; a ground electrode disposed on at least one of an upper surface and a lower surface of the laminated body; first to third resonance electrodes having a strip shape and sequentially arranged side-by-side, as viewed in the stacking direction, on the same interlayer or different interlayers of the laminated body such that the first to third resonance electrodes are electromagnetically coupled to each other, the first to third resonance electrodes being grounded at one end and constituting first to third resonators, respectively; a first input/output coupling electrode having a strip shape and disposed in an interlayer of the laminated body, the interlayer being different from the interlayer where the first resonance electrode is disposed, such that the first input/output coupling electrode faces the first resonance electrode and is electromagnetically coupled thereto; a second input/output coupling electrode having a strip shape and disposed in an interlayer of the laminated body, the interlayer being different from the interlayer where the second resonance electrode is disposed, such that the second input/output coupling electrode faces the second resonance electrode and is electromagnetically coupled thereto; and a resonator coupling electrode disposed in an interlayer of the laminated body, the interlayer being different from both the interlayer where the first resonance electrode is disposed and the interlayer where the third resonance electrode is disposed, and configured to provide electromagnetic coupling between the first resonance electrode and the third resonance electrode. The first and second resonators have the same resonance frequency which is different from a resonance frequency of the third resonator. The first to third resonators are used to produce a passband.

In the bandpass filter of the present invention, in the configuration described above, the first to third resonance electrodes may be disposed in the same interlayer of the laminated body.

In the bandpass filter of the present invention, in the configuration described above, the ground electrode may be disposed on the lower surface of the laminated body; the first and third resonance electrodes may be spaced side-by-side on a first interlayer of the laminated body; and the second resonance electrode may be disposed in a second interlayer of the laminated body, the second interlayer being above the first interlayer, such that the second resonance electrode is located between the first and third resonance electrodes as viewed in the stacking direction.

In the bandpass filter of the present invention, in any of the configurations described above, the first to third resonance electrodes may be disposed such that the grounded ends thereof are staggered as viewed in the stacking direction, the first resonance electrode and the third resonance electrode may be electromagnetically coupled mainly capacitively to each other through the resonator coupling electrode, and the resonance frequency of the first and second resonators may be set to be higher than the resonance frequency of the third resonator.

In the bandpass filter of the present invention, in any of the configurations described above, the first to third resonance electrodes may be disposed such that the grounded ends thereof are staggered as viewed in the stacking direction, the first resonance electrode and the third resonance electrode may be electromagnetically coupled mainly inductively to each other through the resonator coupling electrode, and the resonance frequency of the first and second resonators may be set to be lower than the resonance frequency of the third resonator.

A wireless communication module according to the present invention includes an RF unit including the bandpass filter according to any one of the configurations described above, and a baseband unit connected to the RF unit.

A wireless communication device according to the present invention includes an RF unit including the bandpass filter according to any one of the configurations described above, a baseband unit connected to the RF unit, and an antenna connected to the RF unit.

### Advantageous Effects of Invention

In the bandpass filter according to the present invention having the configuration described above, two resonance peaks of an even mode and an odd mode are formed by electromagnetic coupling between the first and second resonators that are adjacent and have the same resonance frequency. Additionally, the third resonance peak is formed by direct electromagnetic coupling of the third resonator having a resonance frequency different from that of the first and second resonators to the second resonator and, at the same time, by electromagnetic coupling of the third resonator through the resonator coupling electrode to the first resonator. Thus, since these three resonance peaks can be used to produce a passband, a bandpass filter for a wide frequency band can be realized. Moreover, since frequencies of the three resonance peaks can be set to any values, a bandpass filter having a large degree of freedom in designing a passband can be realized.

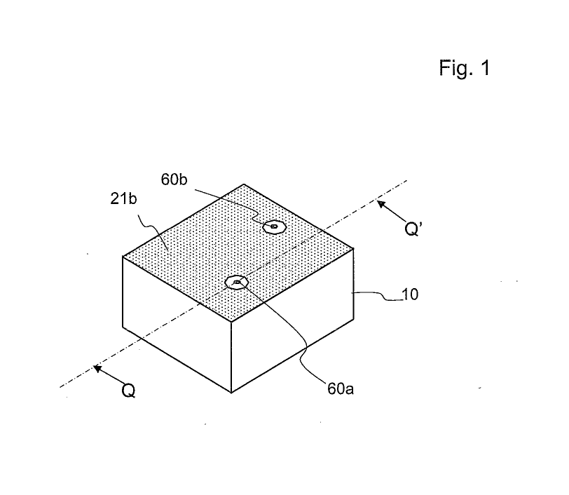

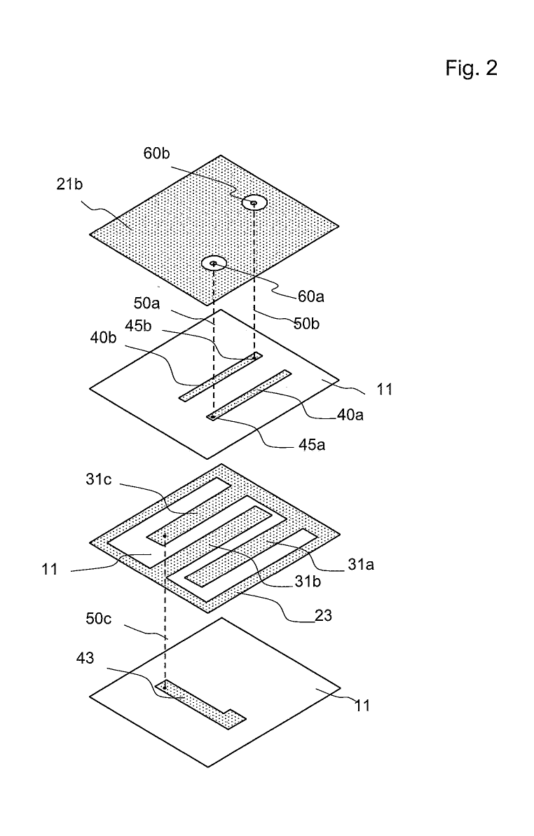

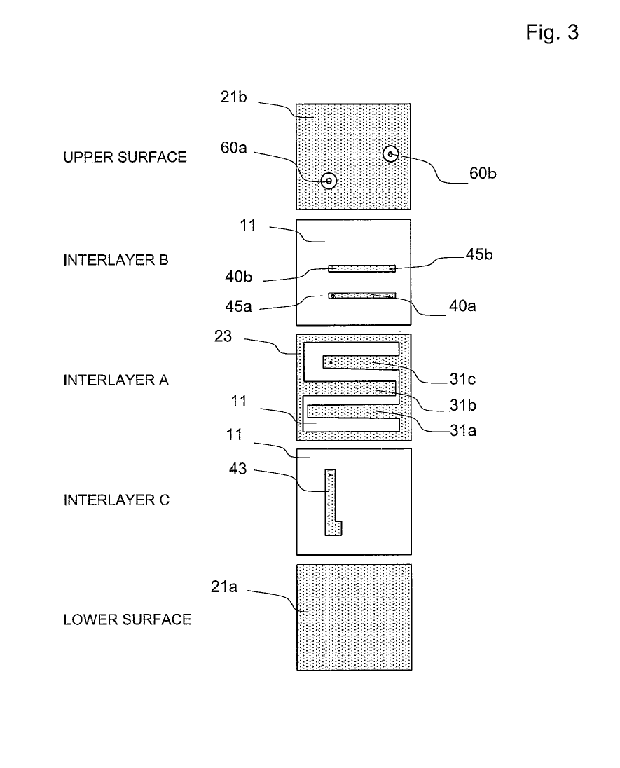

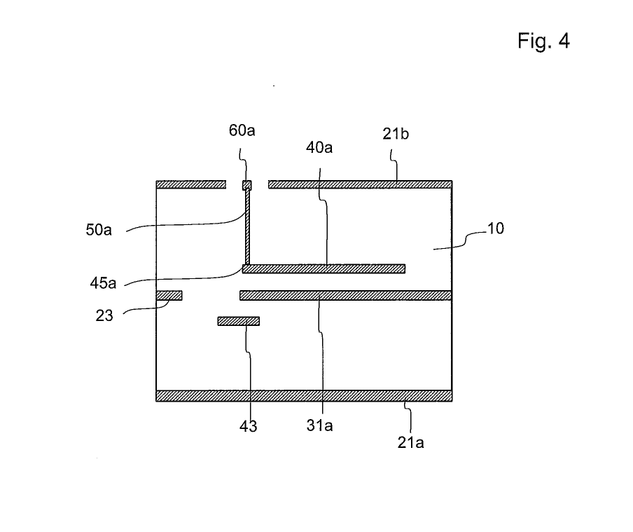

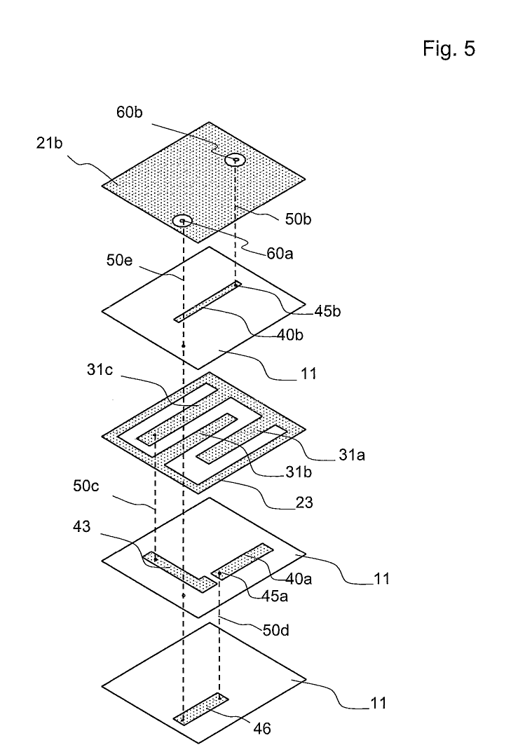

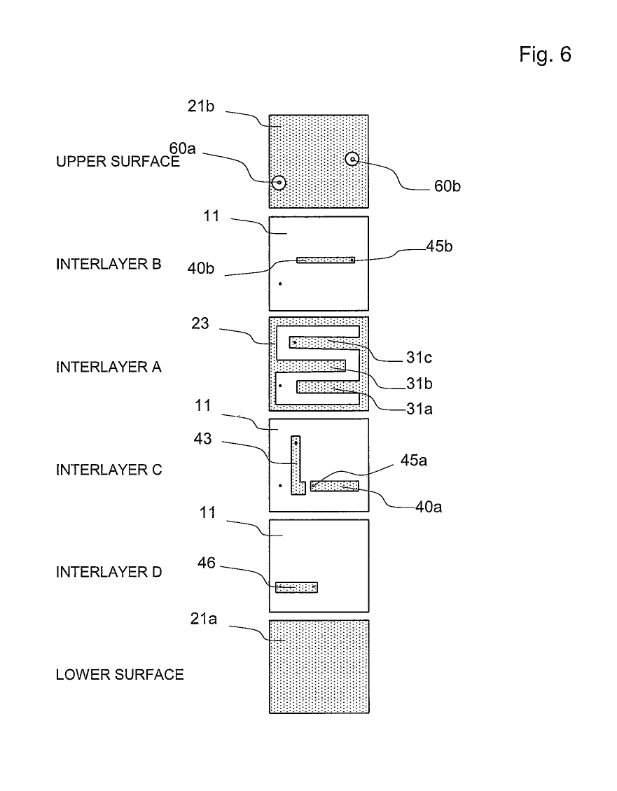

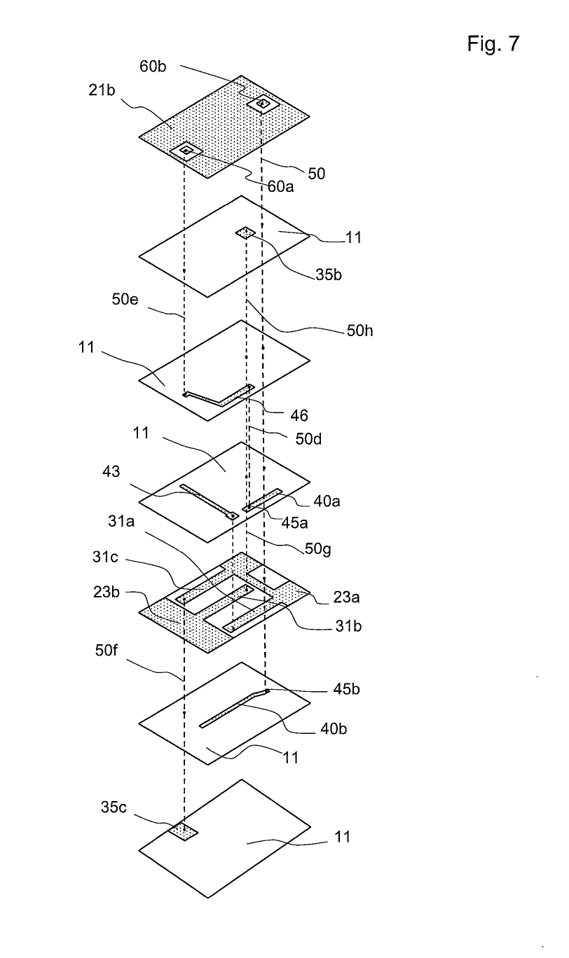

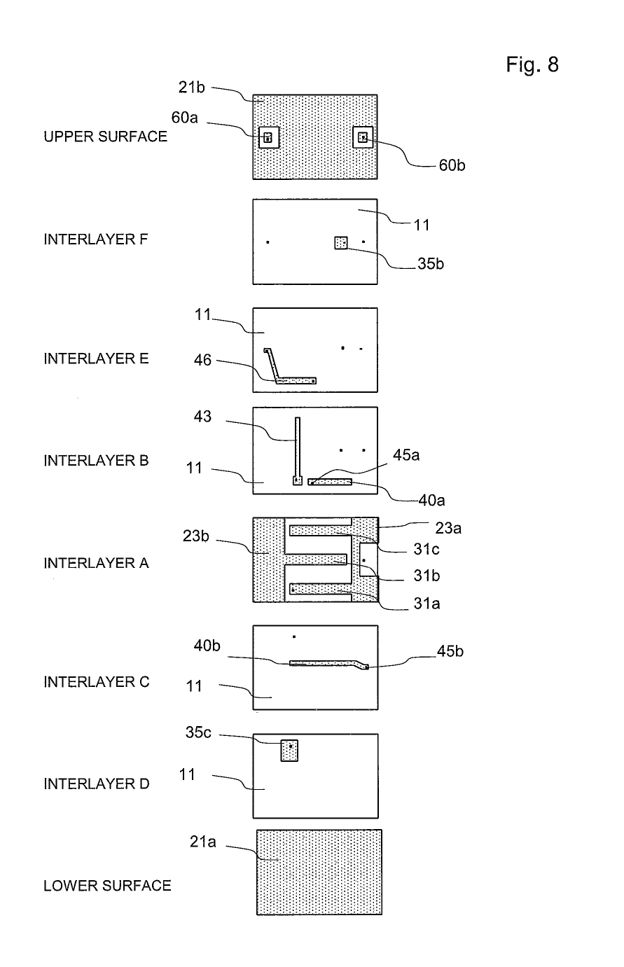

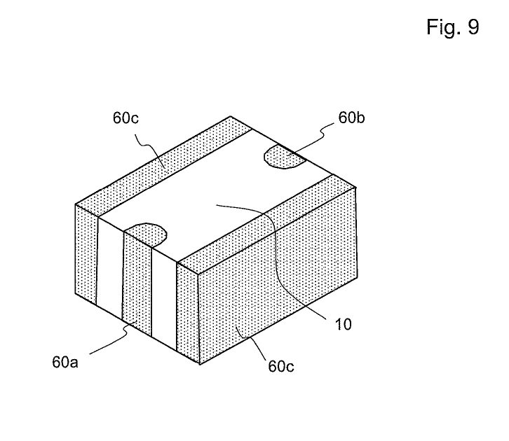

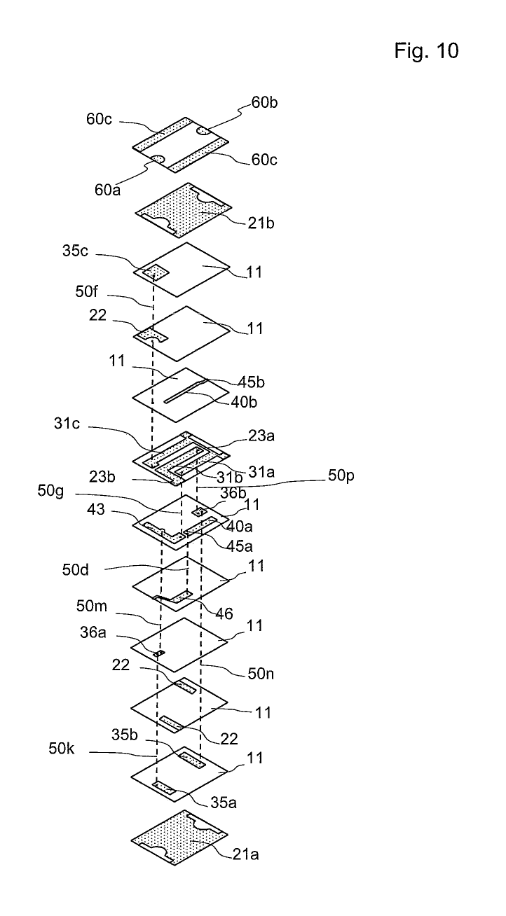

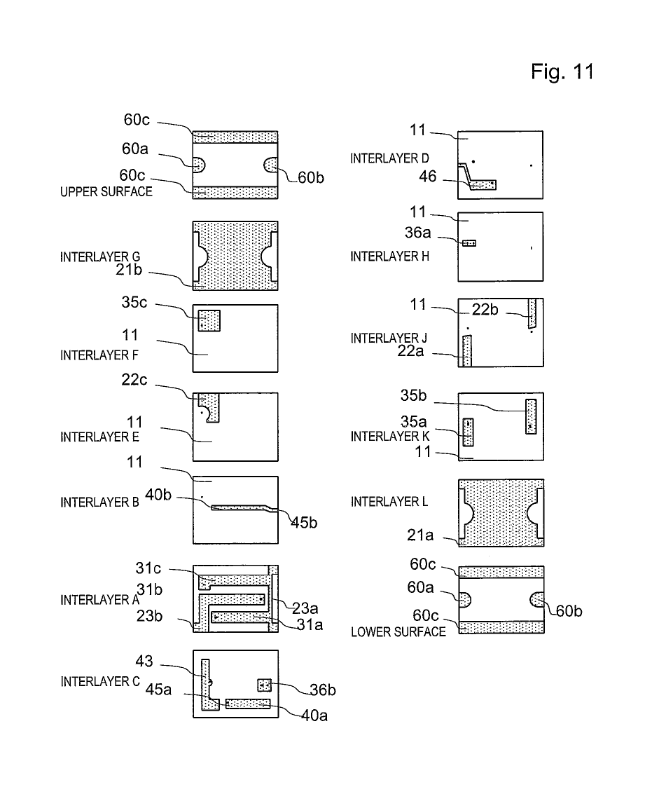

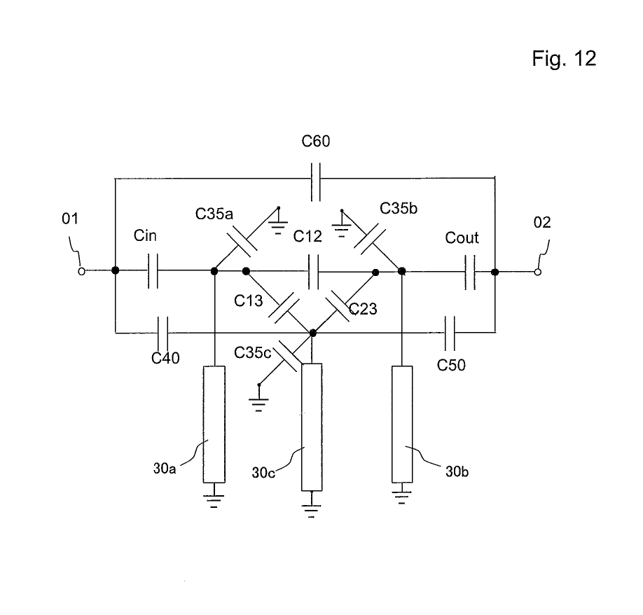

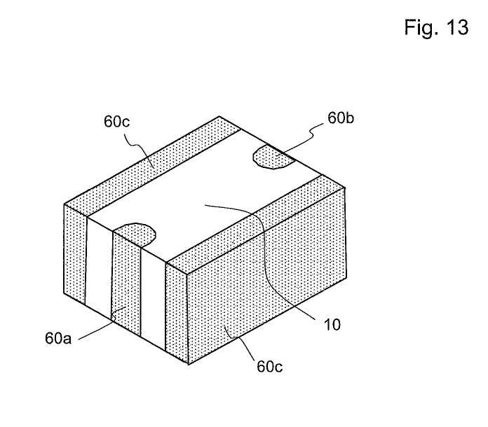

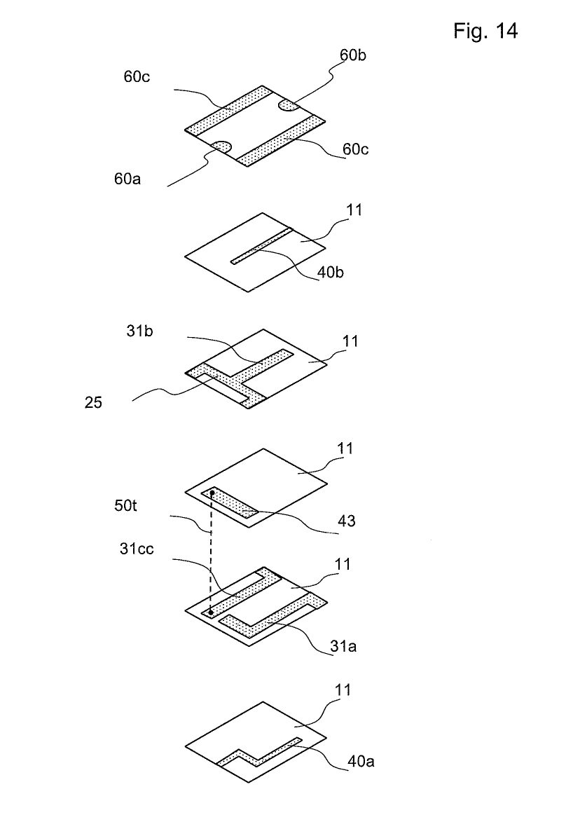

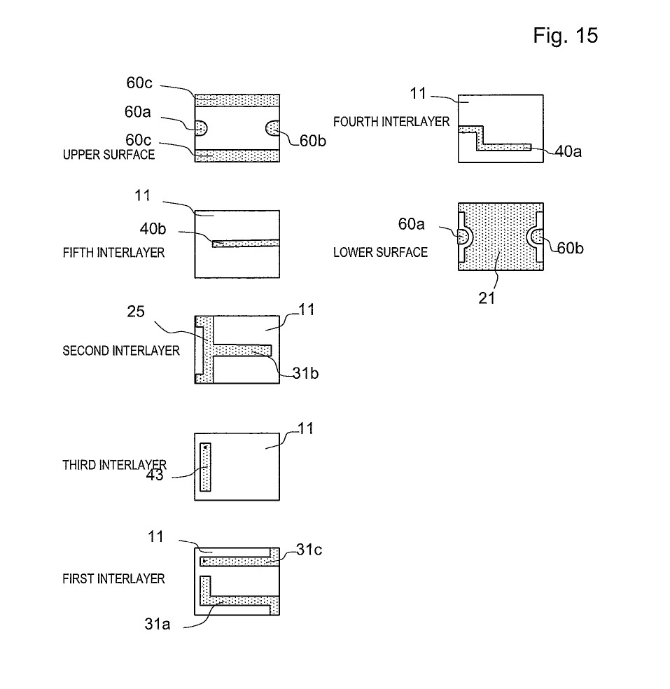

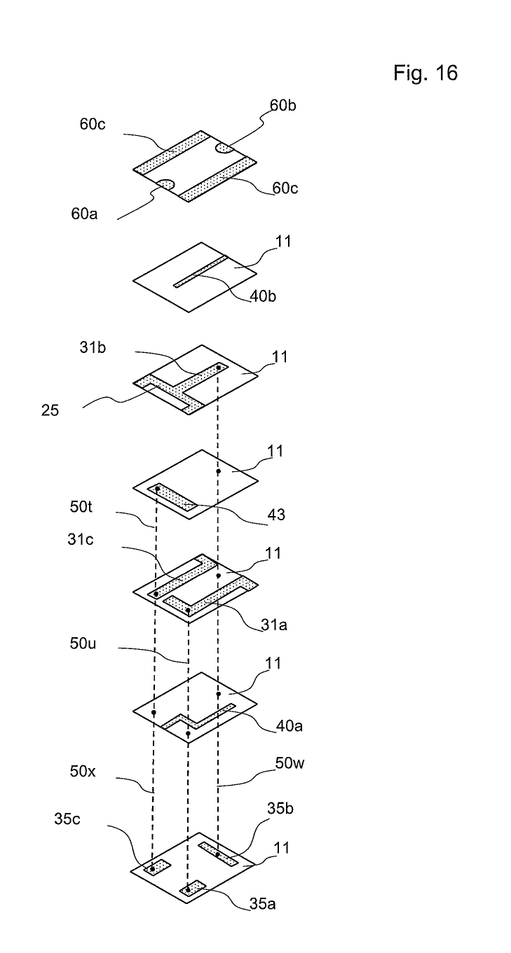

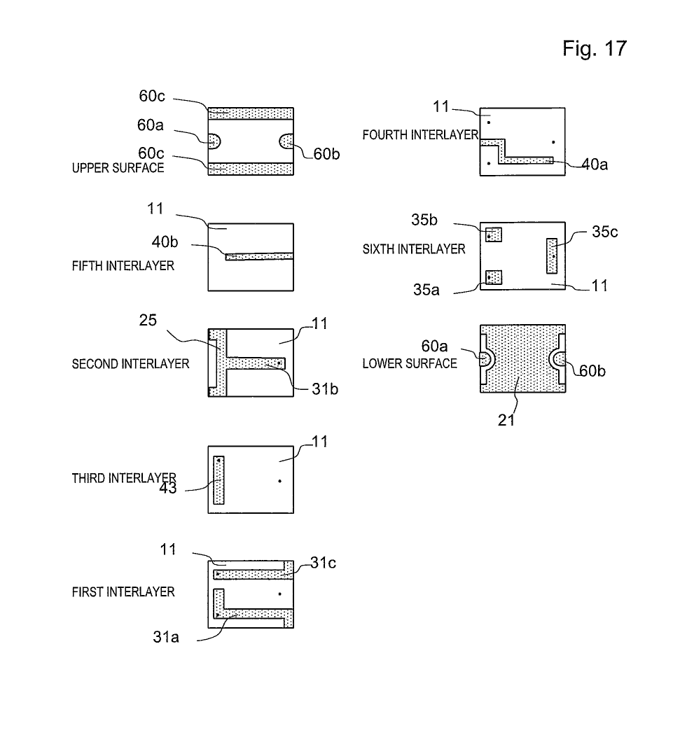

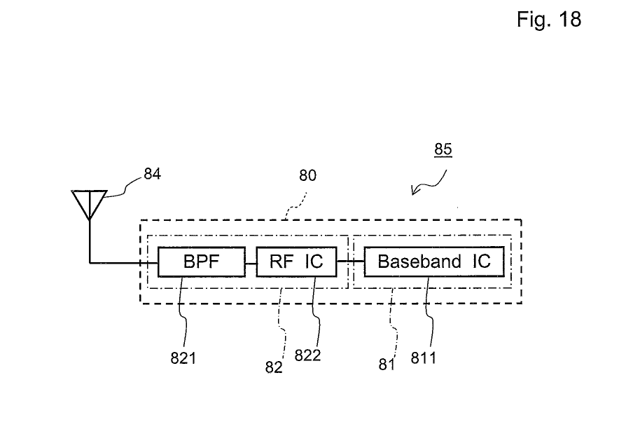

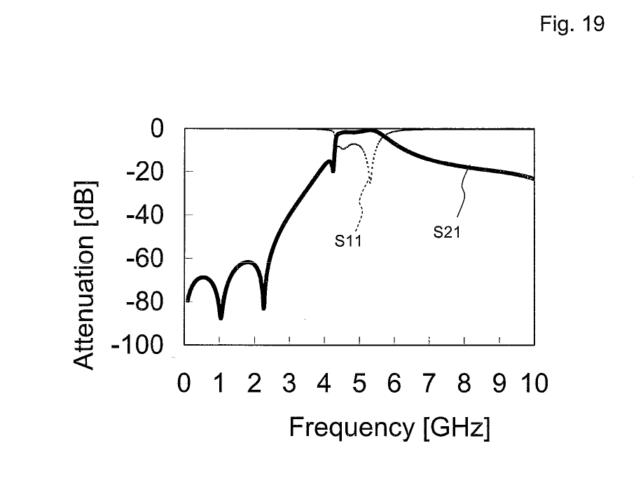

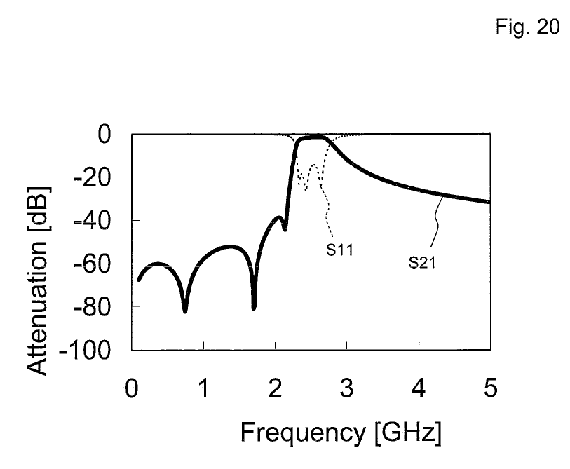

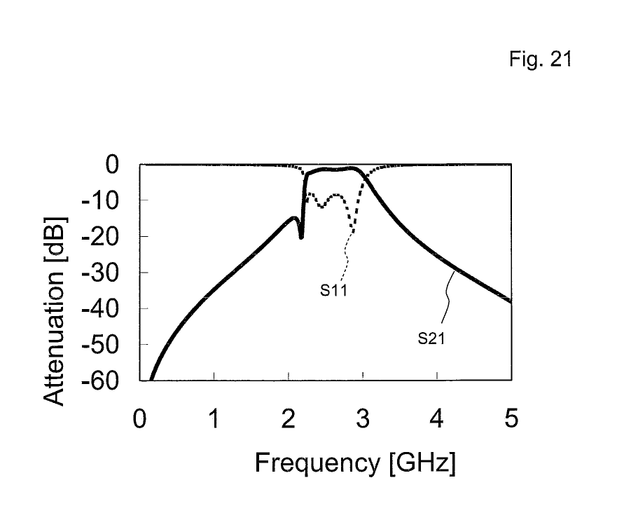

### BRIEF DESCRIPTION OF DRAWINGS

[FIG. 1] FIG. 1 is an external perspective view schematically illustrating a bandpass filter according to a first embodiment of the present invention.

[FIG. 2] FIG. 2 is a schematic exploded perspective view of the bandpass filter illustrated in FIG. 1.

[FIG. 3] FIG. 3 is a plan view schematically illustrating upper and lower surfaces and interlayers of the bandpass filter illustrated in FIG. 1.

[FIG. 4] FIG. 4 is a cross-sectional view taken along line Q-Q′ of the bandpass filter illustrated in FIG. 1.

[FIG. 5] FIG. 5 is an exploded perspective view schematically illustrating a bandpass filter according to a second embodiment of the present invention.

[FIG. 6] FIG. 6 is a plan view schematically illustrating upper and lower surfaces and interlayers of the bandpass filter illustrated in FIG. 5.

[FIG. 7] FIG. 7 is an exploded perspective view schematically illustrating a bandpass filter according to a third embodiment of the present invention.

[FIG. 8] FIG. 8 is a plan view schematically illustrating upper and lower surfaces and interlayers of the bandpass filter illustrated in FIG. 7.

[FIG. 9] FIG. 9 is an external perspective view schematically illustrating a bandpass filter according to a fourth embodiment of the present invention.

[FIG. 10] FIG. 10 is a schematic exploded perspective view of the bandpass filter illustrated in FIG. 9.

[FIG. 11] FIG. 11 is a plan view schematically illustrating upper and lower surfaces and interlayers of the bandpass filter illustrated in FIG. 9.

[FIG. 12] FIG. 12 is an equivalent circuit diagram of the bandpass filters according to the third and fourth embodiments of the present invention.

[FIG. 13] FIG. 13 is an external perspective view schematically illustrating a bandpass filter according to a fifth embodiment of the present invention.

[FIG. 14] FIG. 14 is a schematic exploded perspective view of the bandpass filter illustrated in FIG. 13.

[FIG. 15] FIG. 15 is a plan view schematically illustrating upper and lower surfaces and interlayers of the bandpass filter illustrated in FIG. 13.

[FIG. 16] FIG. 16 is an exploded perspective view schematically illustrating a bandpass filter according to a sixth embodiment of the present invention.

[FIG. 17] FIG. 17 is a plan view schematically illustrating upper and lower surfaces and interlayers of the bandpass filter illustrated in FIG. 16.

[FIG. 18] FIG. 18 is a block diagram schematically illustrating a wireless communication module and a wireless communication device according to a seventh embodiment of the present invention.

[FIG. 19] FIG. 19 is a graph showing a result of simulation of electrical characteristics of the bandpass filter according to the third embodiment of the present invention.

[FIG. 20] FIG. 20 is graph showing a result of simulation of electrical characteristics of the bandpass filter according to the fourth embodiment of the present invention.

[FIG. 21] FIG. 21 is graph showing a result of simulation of electrical characteristics of the bandpass filter according to the sixth embodiment of the present invention.

### DESCRIPTION OF EMBODIMENTS

A bandpass filter, and a wireless communication module and a wireless communication device that use the bandpass filter according to the present invention will now be described in detail with reference to the attached drawings.

### First Embodiment

FIG. 1 is an external perspective view schematically illustrating a bandpass filter according to a first embodiment of the present invention. FIG. 2 is a schematic exploded perspective view of the bandpass filter illustrated in FIG. 1. FIG. 3 is a plan view schematically illustrating upper and lower surfaces and interlayers of the bandpass filter illustrated in FIG. 1. FIG. 4 is a cross-sectional view taken along line Q-Q′ of the bandpass filter illustrated in FIG. 1.

As illustrated in FIG. 1 to FIG. 4, the bandpass filter of the present embodiment includes a laminated body 10, ground electrodes 21a and 21b, first to third resonance electrodes 31a, 31b, and 31c, a first input/output coupling electrode 40a, a second input/output coupling electrode 40b, and a resonator coupling electrode 43. The laminated body 10 is formed by stacking a plurality of dielectric layers 11. The ground electrode 21a is disposed over the entire lower surface of the laminated body 10. The ground electrode 21b is disposed over substantially the entire upper surface of the laminated body 10. The first to third resonance electrodes 31a, 31b, and 31c are sequentially arranged side-by-side, as viewed in the stacking direction, on an interlayer A of the laminated body 10 such that they are electromagnetically coupled to each other. The first to third resonance electrodes 31a, 31b, and 31c are grounded at one end and form first to third resonators, respectively. The first input/output coupling electrode 40a is a strip-shaped electrode disposed in an interlayer B above the interlayer A of the laminated body 10 such that it faces the first resonance electrode 31a and is electromagnetically coupled thereto. The second input/output coupling electrode 40b is a strip-shaped electrode disposed in the interlayer B of the laminated body 10 such that it faces the second resonance electrode 31b and is electromagnetically coupled thereto. The resonator coupling electrode 43 is disposed in an interlayer C below the interlayer A of the laminated body and provides electromagnetic coupling between the first resonance electrode 31a and the third resonance electrode 31c. A first input/output terminal electrode 60a on the upper surface of the laminated body 10 is spaced from the ground electrode 21b and connected through a feedthrough conductor 50a to the first input/output coupling electrode 40a. A second input/output terminal electrode 60b on the upper surface of the laminated body 10 is spaced from the ground electrode 21b and connected through a feedthrough conductor 50b to the second input/output coupling electrode 40b. An annular ground electrode 23 on the interlayer A of the laminated body 10 is positioned around the first to third resonance electrodes 31a, 31b, and 31c. The first to third resonance electrodes 31a, 31b, and 31c are connected at one end to the annular ground electrode 23 in a staggered manner.

In the bandpass filter of the present embodiment, the resonator coupling electrode 43 is connected at one end through a feedthrough conductor 50c to the other end of the third resonance electrode 31c. The resonator coupling electrode 43 and the third resonance electrode 31c thus form the third resonator. The other end of the resonator coupling electrode 43 faces the other end of the first resonance electrode 31a, with the dielectric layer 11 interposed therebetween, and is electromagnetically coupled mainly capacitively to the first resonance electrode 31a. The resonance frequencies of the first and second resonators are set such that they are equal and higher than the resonance frequency of the third resonator.

In the bandpass filter of the present embodiment, a first input/output point 45a at which an electric signal is input to and output from the first input/output coupling electrode 40a is located to one side of the center of a part of the first input/output coupling electrode 40a facing the first resonance electrode 31a, the one side being close to the other end of the first resonance electrode 31a. Similarly, a second input/output point 45b at which an electric signal is input to and output from the second input/output coupling electrode 40b is located to one side of the center of a part of the second input/output coupling electrode 40b facing the second resonance electrode 31b, the one side being close to the other end of the second resonance electrode 31b.

In the bandpass filter of the present embodiment having the configuration described above, for example, when an electric signal from an external circuit is input through the first input/output terminal electrode 60a and the feedthrough conductor 50a to the first input/output point 45a of the first input/output coupling electrode 40a, the first resonance electrode 31a electromagnetically coupled to the first input/output coupling electrode 40a is excited and, at the same time, the second resonance electrode 31b electromagnetically coupled to the first resonance electrode 31a resonates. When the first resonance electrode 31a resonates, the third resonance electrode 31c electromagnetically coupled through the resonator coupling electrode 43 to the first resonance electrode 31a also resonates. The resulting energy is transmitted to the second resonance electrode 31b electromagnetically coupled to the third resonance electrode 31c. Through these two routes, electric signals are transmitted to the second resonance electrode 31b. Then, the electric signals are output from the second input/output point 45b of the second input/output coupling electrode 40b electromagnetically coupled to the second resonance electrode 31b, through the feedthrough conductor 50b and the second input/output terminal electrode 60b, to an external circuit.

In the bandpass filter of the present embodiment, two resonance peaks of an even mode and an odd mode are formed by electromagnetic coupling between the first and second resonators that are adjacent and have the same resonance frequency. Additionally, the third resonance peak is formed by direct electromagnetic coupling of the third resonator having a resonance frequency lower than that of the first and second resonators to the second resonator and, at the same time, by electromagnetic coupling of the third resonator through the resonator coupling electrode 43 to the first resonator. Thus, since these three resonance peaks can be used to produce a passband, a bandpass filter for a wide frequency band can be realized. Moreover, since frequencies of the three resonance peaks can be set to any values, a bandpass filter having a large degree of freedom in designing a passband can be realized.

In the bandpass filter of the present embodiment, the first to third resonance electrodes 31a, 31b, and 31c are staggered at their grounded ends, and are electromagnetically coupled to each other in an interdigital form. Therefore, the electromagnetic coupling between the first resonance electrode 31a and the second resonance electrode 31b and the electromagnetic coupling between the second resonance electrode 31b and the third resonance electrode 31c both are mainly capacitive. At the same time, the first resonance electrode 31a and the third resonance electrode 31c are electromagnetically coupled mainly capacitively to each other, through the resonator coupling electrode 43. Thus, the first to third resonators are all electromagnetically coupled mainly capacitively to each other. Additionally, the resonance frequency of the first and second resonators is set to be higher than that of the third resonator. Therefore, between an electric signal directly transmitted from the first resonator to the second resonator and a signal transmitted from the first resonator through the third resonator to the second resonator, a phase inversion does not occur in the frequency range of the three resonance peaks but occurs at frequencies lower than the frequency range of the three resonance peaks. Thus, a bandpass filter having good transmission characteristics can be realized in which there is no attenuation pole within a passband including frequencies of the three resonance peaks and there is one or more attenuation poles outside the passband, that is, at frequencies lower than those of the three resonance peaks.

A mechanism for realizing the above-described effects will be described in more detail. In the bandpass filter of the present embodiment, there are an electric signal directly transmitted from the first resonance electrode 31a constituting the first resonator to the second resonance electrode 31b constituting the second resonator, and a signal transmitted from the first resonance electrode 31a through the third resonance electrode 31c constituting the third resonator to the second resonance electrode 31b. In a frequency range outside the frequencies of two resonance peaks of even mode resonance and odd mode resonance in a resonance system composed of the first resonator and the second resonator, the transmission route through which the electric signal is directly transmitted from the first resonance electrode 31a to the second resonance electrode 31b is equivalent to an inductor if the first resonance electrode 31a and the second resonance electrode 31b are mainly inductively coupled, but is equivalent to a capacitor if the first resonance electrode 31a and the second resonance electrode 31b are mainly capacitively coupled.

If the electromagnetic coupling between the first resonance electrode 31a and the third resonance electrode 31c and the electromagnetic coupling between the third resonance electrode 31c and the second resonance electrode 31b are both mainly inductive or both mainly capacitive, the transmission route through which the electric signal is transmitted from the first resonance electrode 31a through the third resonance electrode 31c to the second resonance electrode 31b is equivalent to an inductor at frequencies lower than the resonance frequency of the second resonator, but is equivalent to a capacitor at frequencies higher than the resonance frequency of the second resonator. If one of the electromagnetic coupling between the first resonance electrode 31a and the third resonance electrode 31c and the electromagnetic coupling between the third resonance electrode 31c and the second resonance electrode 31b is mainly inductive and the other is mainly capacitive, the transmission route through which the electric signal is transmitted from the first resonance electrode 31a through the third resonance electrode 31c to the second resonance electrode 31b is equivalent to a capacitor at frequencies lower than the resonance frequency of the second resonator, but is equivalent to an inductor at frequencies higher than the resonance frequency of the second resonator.

As described above, the first to third resonators are electromagnetically coupled mainly capacitively to each other, and the resonance frequency of the first and second resonators is set to be higher than that of the third resonator. Therefore, between an electric signal directly transmitted from the first resonator to the second resonator and a signal transmitted from the first resonator through the third resonator to the second resonator, a phase inversion does not occur in the frequency range of the three resonance peaks but occurs at frequencies lower than the frequency range of the three resonance peaks. Thus, a bandpass filter having good transmission characteristics can be realized in which there is no attenuation pole within a passband including frequencies of the three resonance peaks and there is one or more attenuation poles outside the passband, that is, at frequencies lower than those of the three resonance peaks.

In the bandpass filter of the present embodiment, the dielectric layers 11 can be made of resin, such as epoxy resin, or of ceramic, such as dielectric ceramic. For example, a glass-ceramic material is preferably used which is composed of a dielectric ceramic material, such as BaTiO₃, Pb₄Fe₂Nb₂O₁₂, or TiO₂, and a glass material, such as B₂O₃, SiO₂, Al₂O₃, or ZnO, and can be fired at relatively low temperatures ranging from about 800° C. to 1200° C. The thickness of each dielectric layer 11 is set to, for example, about 0.01 mm to 0.1 mm.

As a material of the various electrodes and feedthrough conductors described above, a conductive material mainly composed of Ag or Ag alloy, such as Ag—Pd or Ag—Pt, or a Cu-based, W-based, Mo-based, or Pd-based conductive material is preferably used. The thickness of each of the various electrodes is set to, for example, 0.001 mm to 0.2 mm.

The bandpass filter of the present embodiment can be made, for example, by the following process. First, slurry is made by adding appropriate organic solvents and others to ceramic raw powder and mixing them, so that ceramic green sheets are produced by a doctor blade method. Next, through holes for forming feedthrough conductors are created in the resulting ceramic green sheets by a punching machine or the like. The through holes are filled with a conductive paste containing a conductor of Ag, Ag—Pd, Au, or Cu. At the same time, a conductive paste of the same type is applied to surfaces of the ceramic green sheets using a print method. Thus, the ceramic green sheets with conductive paste are made. Next, the ceramic green sheets with conductive paste are stacked, press-bonded by a hot pressing machine, and fired at a peak temperature of about 800° C. to 1050° C.

### Second Embodiment

FIG. 5 is an exploded perspective view schematically illustrating a bandpass filter according to a second embodiment of the present invention. FIG. 6 is a plan view schematically illustrating upper and lower surfaces and interlayers of the bandpass filter illustrated in FIG. 5. In the present embodiment, a description will be given only of differences from the first embodiment described above. The same components are denoted by the same reference numerals, and a redundant description will be omitted.

In the bandpass filter of the present embodiment, as illustrated in FIG. 5 and FIG. 6, the first input/output coupling electrode 40a and the resonator coupling electrode 43 are disposed in the interlayer C of the laminated body. The first input/output coupling electrode 40a is connected through a feedthrough conductor 50d to a first connection electrode 46 disposed in an interlayer D below the interlayer C. The first connection electrode 46 is connected through a feedthrough conductor 50e to the first input/output terminal electrode 60a.

In the bandpass filter of the present embodiment having the configuration described above, the first input/output coupling electrode 40a and the second input/output coupling electrode 40b are disposed separately on the interlayer C and the interlayer B, respectively, on opposite sides of the interlayer A. It is thus possible to prevent the electromagnetic coupling between the first input/output coupling electrode 40a and the second input/output coupling electrode 40b from becoming too strong.

### Third Embodiment

FIG. 7 is an exploded perspective view schematically illustrating a bandpass filter according to a third embodiment of the present invention. FIG. 8 is a plan view schematically illustrating upper and lower surfaces and interlayers of the bandpass filter illustrated in FIG. 7. In the present embodiment, a description will be given only of differences from the second embodiment described above. The same components are denoted by the same reference numerals, and a redundant description will be omitted.

In the bandpass filter of the present embodiment, as illustrated in FIG. 7 and FIG. 8, an inner-layer ground electrode 23a and-an inner-layer ground electrode 23b, instead of the annular ground electrode 23, are disposed in the first interlayer. The first resonance electrode 31a and the third resonance electrode 31c are connected at one end to the inner-layer ground electrode 23a, and the second resonance electrode 31b is connected at one end to the inner-layer ground electrode 23b. The first input/output coupling electrode 40a is disposed in the interlayer B, and the second input/output coupling electrode 40b is disposed in the interlayer C. A third capacitance electrode 35c on the interlayer D faces the ground electrode 21a with the dielectric layer 11 interposed therebetween. At the same time, the third capacitance electrode 35c is connected through a feedthrough conductor 50f to the other end of the third resonance electrode 31c. The first input/output coupling electrode 40a and the resonator coupling electrode 43 are disposed in the interlayer B. One end of the resonator coupling electrode 43 is connected through a feedthrough conductor 50g to the other end of the first resonance electrode 31a. The other end of the resonator coupling electrode 43 faces the other end of the third resonance electrode 31c, with the dielectric layer 11 interposed therebetween, and is electromagnetically coupled thereto. The first connection electrode 46 is disposed in an interlayer E above the interlayer B. A second capacitance electrode 35b disposed in an interlayer F above the interlayer E faces the ground electrode 21b, with the dielectric layer 11 interposed therebetween. At the same time, the second capacitance electrode 35b is connected through a feedthrough conductor 50h to the other end of the second resonance electrode 31b.

In the bandpass filter of the present embodiment, the first resonator is formed by the first resonance electrode 31a, the resonator coupling electrode 43, and the feedthrough conductor 50g connecting them. The second resonator is formed by the second resonance electrode 31b, the second capacitance electrode 35b, and the feedthrough conductor 50h connecting them. The third resonator is formed by the third resonance electrode 31c, the third capacitance electrode 35c, and the feedthrough conductor 50f connecting them.

In the bandpass filter of the present embodiment having the configuration described above, the length of the second resonance electrode 31b can be reduced by capacitance between the second capacitance electrode 35b and the ground electrode 21b. The length of the third resonance electrode 31c can be reduced by capacitance between the third capacitance electrode 35c and the ground electrode 21a. The length of the first resonance electrode 31a can be reduced by the resonator coupling electrode 43. A compact bandpass filter can thus be realized.

### Fourth Embodiment

FIG. 9 is an external perspective view schematically illustrating a bandpass filter according to a fourth embodiment of the present invention. FIG. 10 is a schematic exploded perspective view of the bandpass filter illustrated in FIG. 9. FIG. 11 is a plan view schematically illustrating upper and lower surfaces and interlayers of the bandpass filter illustrated in FIG. 9. In the present embodiment, a description will be given only of differences from the third embodiment described above. The same components are denoted by the same reference numerals, and a redundant description will be omitted.

In the bandpass filter of the present embodiment, as illustrated in FIG. 9 to FIG. 11, an additional dielectric layer 11 is disposed above the ground electrode 21b on the upper surface of the laminated body, and another additional dielectric layer 11 is disposed below the ground electrode 21a on the lower surface of the laminated body. A new laminated body 10 is thus produced. The first input/output terminal electrode 60a and the second input/output terminal electrode 60b are disposed separately on two opposite sides of the laminated body 10. Ground terminal electrodes 60c connected to the inner-layer ground electrodes 23a and 23b and the ground electrodes 21 are disposed on the other two opposite sides of the laminated body 10.

In the bandpass filter of the present embodiment, the second input/output coupling electrode 40b is disposed in the interlayer B, and connected at one end to the second input/output terminal electrode 60b on the side of the laminated body 10. This means that the second input/output point 45b is a node between the second input/output coupling electrode 40b and the second input/output terminal electrode 60b. The first input/output coupling electrode 40a, the resonator coupling electrode 43, and a third connection electrode 36b are disposed in the interlayer C. The first connection electrode 46 is disposed in the interlayer D. The first connection electrode 46 is connected at one end through the feedthrough conductor 50d to the first input/output point 45a of the first input/output coupling electrode 40a, and directly connected at the other end to the first input/output terminal electrode 60a on the side of the laminated body 10. An inner-layer ground electrode 22c connected to one of the ground terminal electrodes 60c is disposed in the interlayer E to face the third capacitance electrode 35c on the interlayer F. The third capacitance electrode 35c faces the ground electrode 21b on an interlayer G above the interlayer F, with the dielectric layer 11 interposed therebetween. At the same time, the third capacitance electrode 35c is connected through the feedthrough conductor 50f to the other end of the third resonance electrode 31c. A second connection electrode 36a is disposed in an interlayer H below the interlayer D. An inner-layer ground electrode 22a and an inner-layer ground electrode 22b are disposed in an interlayer J below the interlayer H. The inner-layer ground electrode 22a is disposed to face a first capacitance electrode 35a on an interlayer K below the interlayer J. The inner-layer ground electrode 22b is disposed to face the second capacitance electrode 35b on the interlayer K. The two inner-layer ground electrodes 22a and 22b on the interlayer J are connected to the respective ground terminal electrodes 60c. The first capacitance electrode 35a faces the ground electrode 21a on an interlayer L below the interlayer K, with the dielectric layer 11 interposed therebetween. At the same time, the first capacitance electrode 35a is connected through a feedthrough conductor 50k to the second connection electrode 36a. The second connection electrode 36a is connected through a feedthrough conductor 50m to the resonator coupling electrode 43. The resonator coupling electrode 43 faces the other and of the third resonance electrode 31c, with the dielectric layer 11 interposed therebetween. At the same time, the resonator coupling electrode 43 is connected through the feedthrough conductor 50g to the other end of the first resonance electrode 31a. The second capacitance electrode 35b faces the ground electrode 21 on the interlayer L with the dielectric layer 11 interposed therebetween, and is connected through a feedthrough conductor 50n to the third connection electrode 36b. The third connection electrode 36b is connected through a feedthrough conductor 50p to the other end of the second resonance electrode 31b.

In the bandpass filter of the present embodiment, the first resonator is formed by the first resonance electrode 31a, the resonator coupling electrode 43, the second connection electrode 36a, the first capacitance electrode 35a, and the feedthrough conductors 50g, 50m, and 50k connecting them. The second resonator is formed by the second resonance electrode 31b, the third connection electrode 36b, the second capacitance electrode 35b, and the feedthrough conductors 50p and 50n connecting them. The third resonator is formed by the third resonance electrode 31c, the third capacitance electrode 35c, and the feedthrough conductor 50f connecting them.

In the bandpass filter of the present embodiment having the configuration described above, the capacitances between the first to third capacitance electrodes 35a, 35b, and 35c and the ground electrodes 21a and 21b and inner-layer ground electrodes 22a, 22b, and 22c facing the first to third capacitance electrodes 35a, 35b, and 35c are added to the respective first to third resonators. This can further reduce the lengths of the first to third resonance electrodes 31a, 31b, and 31c. A more compact bandpass filter can thus be realized.

An equivalent circuit of the bandpass filters according to the third and fourth embodiments is illustrated in FIG. 12. Reference numerals 01 and 02 denote input/output terminals. Reference numerals 30a, 30b, and 30c denote the first resonator, the second resonator, and the third resonator, respectively. The three resonators are all capacitively coupled to each other by capacitors C12, C13, and C23 formed by direct electromagnetic coupling between the first to third resonance electrodes 31a, 31b, and 31c or by electromagnetic coupling between the first to third resonance electrodes 31a, 31b, and 31c through the resonator coupling electrode 43. A capacitor C60 is formed by electromagnetic coupling between the first input/output coupling electrode 40a and the second input/output coupling electrode 40b. Capacitors C40 and C50 are formed by electromagnetic coupling between the first input/output coupling electrode 40a and the second input/output coupling electrode 40b, and the third resonance electrode 31c. With this configuration, in transmission characteristics of the bandpass filter, three attenuation poles can be formed at frequencies lower than the passband. Reference numerals C35, C36, and C37 denote capacitances formed between the ground potential and the first resonance electrode 31a, the second resonance electrode 31b, and the third resonance electrode 31c by the first capacitance electrode 35a, the second capacitance electrode 35b, and the third capacitance electrode 35c, respectively.

### Fifth Embodiment

FIG. 13 is an external perspective view schematically illustrating a bandpass filter according to a fifth embodiment of the present invention. FIG. 14 is a schematic exploded perspective view of the bandpass filter illustrated in FIG. 13. FIG. 15 is a plan view schematically illustrating upper and lower surfaces and interlayers of the bandpass filter illustrated in FIG. 13.

As illustrated in FIG. 13 to FIG. 15, the bandpass filter of the present embodiment includes the laminated body 10, the first input/output terminal electrode 60a, the second input/output terminal electrode 60b, the ground terminal electrodes 60c, the ground electrode 21a, an internal ground electrode 25, the first to third resonance electrodes 31a, 31b, and 31c, the resonator coupling electrode 43, the strip-shaped first input/output coupling electrode 40a, and the strip-shaped second input/output coupling electrode 40b.

The laminated body 10 is formed by stacking the plurality of dielectric layers 11. The ground terminal electrodes 60c are disposed entirely over a pair of opposite sides of the laminated body 10 and connected to the ground potential. The first input/output terminal electrode 60a and the second input/output terminal electrode 60b on the other pair of opposite sides of the laminated body 10 are spaced from the ground terminal electrodes 60c. The first input/output terminal electrode 60a, the second input/output terminal electrode 60b, and the ground terminal electrodes 60c extend, to some extent, to the upper and lower surfaces of the laminated body 10. The ground electrode 21a is disposed over substantially the entire lower surface of the laminated body 10 and connected to the ground terminal electrodes 60c. The first and third resonance electrodes 31a and 31c are strip-shaped and are spaced side-by-side on a first interlayer of the laminated body 10. The first and third resonance electrodes 31a and 31c are connected to the respective ground terminal electrodes 60c at one end, and grounded to form first and third resonators, respectively. The second resonance electrode 31b is strip-shaped and is disposed in a second interlayer above the first interlayer of the laminated body 10. The second resonance electrode 31b is located between the first and third resonance electrodes 31a and 31c, as viewed in the stacking direction (i.e., as viewed from above), such that the second resonance electrode 31b is electromagnetically coupled to the first and third resonance electrodes 31a and 31c. In other words, the first to third resonance electrodes 31a, 31b, and 31c are sequentially arranged side-by-side, as viewed in the stacking direction, such that they are electromagnetically coupled to each other. The second resonance electrode 31b is connected at one end, through the internal ground electrode 25 on the second interlayer of the laminated body 10, to the ground terminal electrodes 60c and grounded to form a second resonator. The resonator coupling electrode 43 is strip-shaped and is disposed in a third interlayer between the first and second interlayers of the laminated body 10. One end of the resonator coupling electrode 43 is connected through a feedthrough conductor 50t to the other end of the third resonance electrode 31c. The other end of the resonator coupling electrode 43 faces the other end of the first resonance electrode 31a, with the dielectric layer 11 interposed therebetween, and is electromagnetically coupled thereto. The resonator coupling electrode 43 thus provides electromagnetic coupling between the first and third resonance electrodes 31a and 31c. The first resonance electrode 31a and the third resonance electrode 31c are electromagnetically coupled mainly capacitively to each other through the resonator coupling electrode 43. The first input/output coupling electrode 40a is strip-shaped. The first input/output coupling electrode 40a is disposed in a fourth interlayer below the first interlayer of the laminated body 10 such that the first input/output coupling electrode 40a faces the first resonance electrode 31a, with the dielectric layer 11 interposed therebetween, and is electromagnetically coupled thereto. The first input/output coupling electrode 40a is connected at one end to the first input/output terminal electrode 60a. The second input/output coupling electrode 40b is strip-shaped. The second input/output coupling electrode 40b is disposed in a fifth interlayer above the second interlayer of the laminated body 10 such that the second input/output coupling electrode 40b faces the second resonance electrode 31b, with the dielectric layer 11 interposed therebetween, and is electromagnetically coupled thereto. The second input/output coupling electrode 40b is connected at one end to the second input/output terminal electrode 60b.

In the bandpass filter of the present embodiment, the third resonator is formed by the third resonance electrode 31c, the resonator coupling electrode 43, and the feedthrough conductor 50t connecting them. The second resonator is formed by the second resonance electrode 31b and the internal ground electrode 25. The first resonator is formed by the first resonance electrode 31a. The first and second resonators have the same resonance frequency higher than that of the third resonator. The first to third resonators are used to produce a passband.

In the bandpass filter of the present embodiment having the configuration described above, three resonance peaks can be used to produce a passband. Therefore, as in the cases of the bandpass filters of the first to fourth embodiments described above, it is possible to realize a bandpass filter that can be used for a wide frequency band and has a large degree of freedom in designing a passband.

In the bandpass filter of the present embodiment, the first to third resonance electrodes 31a, 31b, and 31c are staggered at their grounded ends, and are electromagnetically coupled to each other in an interdigital form. The first resonance electrode 31a and the third resonance electrode 31c are electromagnetically coupled mainly capacitively to each other, through the resonator coupling electrode 43. Thus, the first to third resonators are all mainly capacitively coupled to each other. Additionally, the resonance frequency of the first and second resonators is set to be higher than that of the third resonator. Therefore, between an electric signal directly transmitted from the first resonator to the second resonator and a signal transmitted from the first resonator through the third resonator to the second resonator, a phase inversion does not occur in the frequency range of the three resonance peaks but occurs at frequencies lower than the frequency range of the three resonance peaks. Thus, a bandpass filter having good transmission characteristics can be realized in which there is no attenuation pole within a passband including frequencies of the three resonance peaks and there is one or more attenuation poles at frequencies lower than the passband.

Additionally, in the bandpass filter of the present embodiment, the ground electrode 21a is disposed on the lower surface of the laminated body 10. The ground terminal electrodes 60c are disposed on two sides of the laminated body 10, the two sides being located at both ends in a direction in which the first to third resonance electrodes 31a, 31b, and 31c are arranged side-by-side as viewed in the stacking direction (i.e., as viewed from above). Also, the ground terminal electrodes 60c extend, to some extent, to the upper and lower surfaces of the laminated body 10, the upper and lower surfaces being adjacent to the two sides of the laminated body 10 described above. On the second interlayer above the first interlayer where there are the first and third resonance electrodes 31a and 31c, the second resonance electrode 31b is disposed such that it is located between the first and third resonance electrodes 31a and 31c as viewed from above. In the bandpass filter of the present embodiment having the configuration described above, it is possible to maximize the distance from the ground electrode 21a and the ground terminal electrodes 60c to the first to third resonance electrodes 31a, 31b, and 31c within the laminated body 10 of limited size. Thus, since the Q-values of the first to third resonators can be maximized, a compact low-loss bandpass filter can be realized.

### Sixth Embodiment

FIG. 16 is an exploded perspective view schematically illustrating a bandpass filter according to a sixth embodiment of the present invention. FIG. 17 is a plan view schematically illustrating upper and lower surfaces and interlayers of the bandpass filter illustrated in FIG. 16. In the present embodiment, a description will be given only of differences from the fifth embodiment described above. The same components are denoted by the same reference numerals, and a redundant description will be omitted.

As illustrated in FIG. 16 and FIG. 17, the bandpass filter of the present embodiment includes the first capacitance electrode 35a, the second capacitance electrode 35b, and the third capacitance electrode 35c that are disposed in a sixth interlayer below the fourth interlayer of the laminated body 10 such that they face the ground electrode 21a. The first capacitance electrode 35a is connected through a feedthrough conductor 50u to the other end of the first resonance electrode 31a. The second capacitance electrode 35b is connected through a feedthrough conductor 50w to the other end of the second resonance electrode 31b. The third capacitance electrode 35c is connected through a feedthrough conductor 50x to the other end of the third resonance electrode 31c.

In the bandpass filter of the present embodiment having the configuration described above, since capacitance is formed between the first capacitance electrode 35a, the second capacitance electrode 35b, and the third capacitance electrode 35c and the ground electrode 21a, it is possible to reduce the lengths of the first resonance electrode 31a, the third resonance electrode 31c, and the second resonance electrode 31. A compact bandpass filter can thus be realized. In the bandpass filter of the present embodiment, a first resonator is formed by the first resonance electrode 31a, the first capacitance electrode 35a, and the feedthrough conductor 50u connecting them. A second resonator is formed by the second resonance electrode 31b, the third capacitance electrode 35c, the feedthrough conductor 50 connecting them, and the internal ground electrode 25. A third resonator is formed by the third resonance electrode 31c, the third capacitance electrode 35c, the resonator coupling electrode 43, and the feedthrough conductors 50t and 50x connecting them.

### Seventh Embodiment

FIG. 18 is a block diagram illustrating a wireless communication module 80 and a wireless communication device 85 according to a seventh embodiment of the present invention.

The wireless communication module 80 of the present embodiment includes, for example, a baseband unit 81 and an RF unit 82. The baseband unit 81 processes a baseband signal. The RF unit 82 is connected to the baseband unit 81 and processes a modulated baseband signal and an undemodulated RF signal. The RF unit 82 includes a bandpass filter 821 described above. The bandpass filter 821 attenuates an RF signal obtained by modulating a baseband signal, or a received RF signal having a frequency outside a communication band. Specifically, the baseband unit 81 includes a baseband IC 811, and the RF unit 82 includes an RF IC 822 between the bandpass filter 821 and the baseband unit 81. There may be other circuits between the baseband IC 811 and the RF IC 822. The wireless communication device 85 of the present embodiment capable of transmitting and receiving RF signals is made by connecting an antenna 84 to the bandpass filter 821 of the wireless communication module 80.

In the wireless communication module 80 and the wireless communication device 85 of the present embodiment having the configuration described above, the bandpass filter 821 of the present invention that can be used for a wide frequency band and has an attenuation pole outside the passband is used to filter a communication signal. It is thus possible to reduce noise and loss of communication signal throughout the communication band. Therefore, since the reception sensitivity can be improved and the degree of amplification of the communication signal can be reduced, power consumption in an amplifying circuit can be reduced. It is thus possible to realize the high-performance wireless communication module 80 and wireless communication device 85 that have high reception sensitivity and consume less power.

(Modifications)

The present invention is not limited to the first to seventh embodiments described above, and can be variously changed and modified without departing from the gist of the present invention.

For example, in the first to sixth embodiments described above, the grounded ends of the first to third resonance electrodes 31a, 31b, and 31c are staggered, adjacent resonance electrodes are electromagnetically coupled mainly capacitively to each other, the first resonance electrode 31a and the third resonance electrode 31c are electromagnetically coupled mainly capacitively to each other through the resonator coupling electrode 43, and the resonance frequency of the first and second resonators is set to be higher than that of the third resonator. However, the present invention is not limited to this. For example, it is allowed that the grounded ends of the first to third resonance electrodes 31a, 31b, and 31c are staggered and adjacent resonance electrodes are electromagnetically coupled mainly capacitively to each other, the first resonance electrode 31a and the third resonance electrode 31c are electromagnetically coupled mainly inductively to each other through the resonator coupling electrode 43, and the resonance frequency of the first and second resonators are set to be lower than that of the third resonator.

In this case, between an electric signal directly transmitted from the first resonator to the second resonator and a signal transmitted from the first resonator through the third resonator to the second resonator, a phase inversion does not occur in the frequency range of the three resonance peaks but occurs at frequencies higher than the frequency range of the three resonance peaks. Thus, a bandpass filter having good transmission characteristics can be realized in which there is no attenuation pole within a passband including frequencies of the three resonance peaks and there is one or more attenuation poles at frequencies higher than the passband.

To provide mainly inductive electromagnetic coupling between the first resonance electrode 31a and the third resonance electrode 31c through the resonator coupling electrode 43, for example, the resonator coupling electrode 43 may be grounded at both ends, one end of the resonator coupling electrode 43 may face one end of the first resonance electrode 31a and be electromagnetically coupled thereto, and the other end of the resonator coupling electrode 43 may face one end of the third resonance electrode 31c and be electromagnetically coupled thereto.

In the first to sixth embodiments described above, the bandpass filter includes the first input/output terminal electrode 60a and the second input/output terminal electrode 60b. However, if the bandpass filter is in a region within a module substrate, the first input/output terminal electrode 60a and the second input/output terminal electrode 60b are not necessarily needed. The same applies to the ground terminal electrodes 60c.

Also in the first to sixth embodiments described above, the bandpass filter is included in one laminated body 10. Alternatively, the bandpass filter may be provided over a plurality of laminated bodies stacked in the thickness direction.

In the first to fourth embodiments described above, the first to third resonance electrodes 31a, 31b, and 31c are disposed in the same interlayer A of the laminated body 10. In the fifth and sixth embodiments described above, the first and third resonance electrodes 31a and 31c are disposed in the first interlayer of the laminated body 10, and the second resonance electrode 31b is disposed in the second interlayer above the first interlayer. However, the present invention is not limited to the embodiments described above. The first to third resonance electrodes 31a, 31b, and 31c may be disposed in either the same or different interlayers. That is, the first to third resonance electrodes 31a, 31b, and 31c may be disposed in any manner as long as they are sequentially arranged side-by-side, as viewed in the stacking direction, such that they are electromagnetically coupled to each other. For example, the first and second resonance electrodes 31a and 31b may be disposed in the same interlayer of the laminated body 10, and the third resonance electrode 31c may be disposed in a different interlayer. Alternatively, the first to third resonance electrodes 31a, 31b, and 31c may be disposed in different interlayers.

### EXAMPLES

Specific examples of the bandpass filter according to the present invention will now be described.

Electrical characteristics of the bandpass filter according to the third embodiment illustrated in FIG. 7 and FIG. 8, the bandpass filter according to the fourth embodiment illustrated in FIG. 9 to FIG. 11, and the bandpass filter according to the sixth embodiment illustrated in FIG. 16 and FIG. 17 were calculated by simulation using a finite element method.

In the simulation of the bandpass filter of the third embodiment, the first to third resonance electrodes 31a, 31b, and 31c were rectangular, 0.25 mm wide, and 1.5 mm long. The second capacitance electrode 35b was 0.3 mm square. The third capacitance electrode 35c was rectangular, 0.4 mm wide, and 0.5 mm long. The resonator coupling electrode 43 was rectangular, 0.1 mm wide, and 1.4 mm long. The overall shape of the bandpass filter was a rectangular parallelepiped 2.0 mm wide, 3.0 mm long, and 1.0 mm high. The relative dielectric constant of the dielectric layers 11 was 18.7.

In the simulation of the bandpass filter of the fourth embodiment, the first resonance electrode 31a was rectangular, 0.35 mm wide, and 1.9 mm long. The second resonance electrode 31b was rectangular, 0.35 mm wide, and 2.1 mm long. The third resonance electrode 31c was rectangular, 0.35 mm wide, and 2.2 mm long. The first capacitance electrode 35a was rectangular, 0.3 mm wide, and 0.88 mm long. The second capacitance electrode 35b was rectangular, 0.33 mm wide, and 1.1 mm long. The third capacitance electrode 35c was 0.69 mm square. The first input/output coupling electrode 40a was rectangular, 0.3 mm wide, and 1.4 mm long. The second input/output coupling electrode 40b was rectangular, 0.14 mm wide, and 2.1 mm long. The overall shape of the bandpass filter was a rectangular parallelepiped 2.0 mm wide, 2.5 mm long, and 0.9 mm high. The relative dielectric constant of the dielectric layers 11 was 18.7.

In the simulation of the bandpass filter of the sixth embodiment, the first resonance electrode 31a was in the shape of a bent strip 0.31 mm wide and about 2.4 mm long. The third resonance electrode 31c was in the shape of a bent strip 0.31 mm wide and about 2 mm long. The second resonance electrode 31b was strip-shaped, 0.21 mm wide, and 2 mm long. The resonator coupling electrode 43 was strip-shaped, 0.25 mm wide, and 1.28 mm long. The first input/output coupling electrode 40a was in the shape of a bent strip 0.15 mm wide and about 2 mm long. The second input/output coupling electrode 40b was strip-shaped, 0.15 mm wide, and 2 mm long. The first, capacitance electrode 35a was rectangular, 0.6 mm wide, and 0.8 mm long. The second capacitance electrode 35b was rectangular, 0.6 mm wide, and 1.05 mm long. The third capacitance electrode 35c was rectangular, 0.35 mm wide, and 1 mm long. The laminated body 10 was in the shape of a rectangular parallelepiped 1.6 mm wide, 2.5 mm long, and 0.9 mm thick. The relative dielectric constant of the dielectric layers 11 was 18.7.

FIG. 19, FIG. 20, and FIG. 21 are graphs showing results of the simulations. In the graphs, the horizontal axis represents frequency and the vertical axis represents attenuation. Specifically, transmission characteristics (S21) and reflection characteristics (S11) of the bandpass filters are shown in the graphs. FIG. 19 is a graph showing characteristics of the bandpass filter according to the third embodiment. FIG. 20 is graph showing characteristics of the bandpass filter according to the fourth embodiment. FIG. 21 is graph showing characteristics of the bandpass filter according to the sixth embodiment.

The graphs of FIG. 19 and FIG. 20 show that both of the bandpass filters have good transmission characteristics in which a wide and flat passband is achieved, three attenuation poles are formed at frequencies lower than the passband, and a sufficient attenuation is obtained at frequencies lower than the passband. The attenuation pole at a frequency closest to the passband is formed by providing capacitive coupling between all the first to third resonators and by setting the resonance frequencies of the first and second resonators to be equal and higher than that of the third resonator. The other two attenuation poles at lower frequencies are formed by addition of C40, C50, and C60 in the equivalent circuit of FIG. 12. The graph of FIG. 21 shows that the bandpass filter has good transmission characteristics in which a flat and very wide passband ranging from about 2.3 GHz to 3 GHz is achieved, an attenuation pole is formed near the lower frequencies of the passband, and a sufficient attenuation is obtained near the lower frequencies of the passband. These results have proven the effectiveness of the present invention.

### REFERENCE SIGNS LIST

10: laminated body
11: dielectric layer
21a, 21b: ground electrode
31a: first resonance electrode
31b: second resonance electrode
31c: third resonance electrode
40a: first input/output coupling electrode
40b: second input/output coupling electrode
43: resonator coupling electrode
80: wireless communication module
81: baseband unit
82: RF unit
84: antenna
85: wireless communication device
821: bandpass filter

1. A bandpass filter comprising:
a laminated body formed by stacking a plurality of dielectric layers;
a ground electrode disposed on at least one of an upper surface and a lower surface of the laminated body;
first to third resonance electrodes having a strip shape and sequentially arranged side-by-side, as viewed in the stacking direction, on the same interlayer or different interlayers of the laminated body such that the first to third resonance electrodes are electromagnetically coupled to each other, the first to third resonance electrodes being grounded at one end and constituting first to third resonators, respectively;
a first input/output coupling electrode having a strip shape and disposed in an interlayer of the laminated body, the interlayer being different from the interlayer where the first resonance electrode is disposed, such that the first input/output coupling electrode faces the first resonance electrode and is electromagnetically coupled thereto;
a second input/output coupling electrode having a strip shape and disposed in an interlayer of the laminated body, the interlayer being different from the interlayer where the second resonance electrode is disposed, such that the second input/output coupling electrode faces the second resonance electrode and is electromagnetically coupled thereto; and
a resonator coupling electrode disposed in an interlayer of the laminated body, the interlayer being different from both the interlayer where the first resonance electrode is disposed and the interlayer where the third resonance electrode is disposed, and configured to provide electromagnetic coupling between the first resonance electrode and the third resonance electrode,
wherein the first and second resonators have the same resonance frequency which is different from a resonance frequency of the third resonator; and
the first to third resonators are used to produce a passband.

2. The bandpass filter according to claim 1, wherein the first to third resonance electrodes are disposed in the same interlayer of the laminated body.

3. The bandpass filter according to claim 1, wherein the ground electrode is disposed on the lower surface of the laminated body;
the first and third resonance electrodes are spaced side-by-side on a first interlayer of the laminated body; and
the second resonance electrode is disposed in a second interlayer of the laminated body, the second interlayer being above the first interlayer, such that the second resonance electrode is located between the first and third resonance electrodes as viewed in the stacking direction.

4. The bandpass filter according to claim 1, wherein the first to third resonance electrodes are disposed such that the grounded ends thereof are staggered as viewed in the stacking direction, the first resonance electrode and the third resonance electrode are electromagnetically coupled mainly capacitively to each other through the resonator coupling electrode, and the resonance frequency of the first and second resonators is set to be higher than the resonance frequency of the third resonator.

5. The bandpass filter according to claim 1, wherein the first to third resonance electrodes are disposed such that the grounded ends thereof are staggered as viewed in the stacking direction, the first resonance electrode and the third resonance electrode are electromagnetically coupled mainly inductively to each other through the resonator coupling electrode, and the resonance frequency of the first and second resonators is set to be lower than the resonance frequency of the third resonator.

6. A wireless communication module comprising an RF unit including the bandpass filter according to claim 1; and a baseband unit connected to the RF unit.

7. A wireless communication device comprising an RF unit including the bandpass filter according to claim 1; a baseband unit connected to the RF unit; and an antenna connected to the RF unit.
